(19) United States
(12) Patent Application Publication
(10) Pub. No.: US 2013/0120075 A1
(43) Pub. Date: May 16, 2013

(54) PULSE WIDTH MODULATION DEVICE

(71) Applicant: Shinetsu KATOU, Osaka (JP)

(72) Inventor: Shinetsu KATOU, Osaka (JP)

(73) Assignee: PANASONIC CORPORATION, Osaka (JP)

(21) Appl. No.: 13/611,527

(22) Filed: Sep. 12, 2012

(30) Foreign Application Priority Data
Nov. 11, 2011 (JP) 2011-247167

(51) Int. Cl. H03K 7/08

(52) U.S. Cl. 332/109

(57) ABSTRACT

The present disclosure provides a high-stability pulse width modulation device which easily changes distortion compensation characteristics of an output pulse signal. The pulse width modulation device modulates a digital signal to a pulse signal having a pulse width corresponding to the value of the signal. A quantizer converts an output of a noise shaping filter to a digital signal with a small bit number. The pulse width modulator converts an output of the quantizer to the pulse signal. A compensation circuit receives the output of the quantizer, and outputs a compensation signal for compensating non-linear distortion of the pulse signal. The noise shaping filter receives both of the output of the quantizer and the compensation signal, and executes noise shaping of the input digital signal.

### CROSS-REFERENCE TO RELATED APPLICATION

This application claims priority to Japanese Patent Application No. 2011-247167 filed on Nov. 11, 2011, the disclosure of which including the specification, the drawings, and the claims is hereby incorporated by reference in its entirety.

### BACKGROUND

The present disclosure relates to pulse width modulation devices used for digital audio power amplifiers performing high-efficiency power amplification using, for example, switching.

Conventionally, the mainstream of audio players has been stereos. In recent years, the stereos are replaced with what is called audio visual (AV) equipment such as DVDs and BDs which also provide video images. In such AV equipment, an additional channel (ch) called a surround channel is used for a sound system to provide an increasing dynamic and realistic sound. High-efficiency switching amplifiers are used for multichannel sound reproduction, and sound reproduction with low power consumption.

Such a switching amplifier includes a full digital amplifier performing digital processing specializing in digital signals. A general full digital amplifier converts an input signal of 16 bits or 24 bits to several-bit data using signal processing called noise shaping, inputs the signal to a pulse width modulator, and converts the signal to a 1-bit signal with a variable pulse width. The converted pulse train is amplified by a power switch, and the output pulse train passes through a low-pass filter, thereby capturing an audio signal. A speaker is driven by the audio signal. FIG. 5 illustrates the configuration of a pulse width modulation device shown in Japanese Patent Publication No. 2005-236928. A noise shaping filter 3 calculates an error between an input signal and an output of a non-linear function table 35, performs the above-described noise shaping calculation of an error component, and outputs the calculation result to a quantizer 1. The quantizer 1 deletes lower bits of the input signal of, for example, 24 bits, and outputs, for example, a 6-bit signal. The output of the quantizer 1 is converted to a 1-bit signal having 64 types of pulse widths in a pulse width modulator (PWM) 2. If the output pulse is smoothed by a filter, a high voltage is obtained from a pulse with a great width, and a low voltage is obtained from a pulse with a small width. That is, an output voltage corresponding to the input signal is obtained, and a sound can be heard by supplying the output voltage to a speaker.

### SUMMARY

In FIG. 5, a non-linear function table 35 stores the correspondence relationship between the output of the quantizer 1 and a result of non-linear calculation for distortion compensation, and outputs a non-linear element e(y) corresponding to the output y of the quantizer 1. The feature of Japanese Patent Publication No. 2005-236928 is that feedback is performed through the non-linear element e(y) instead of conventional feedback, thereby compensating distortion.

In the above-described configuration, however, when the characteristics of the non-linear element are to be changed a little due to a change in the operating voltage, the entire table of the non-linear element e(y) needs to be rewritten, and a considerable change is required.

Since the stability of the processing may be problematic in changing the non-linear processing, great efforts may be required to check operation. In view of the problem, the present disclosure provides a high-stability pulse width modulation device capable of changing distortion compensation characteristics of an output pulse signal.

According to an aspect of the present disclosure, a pulse width modulation device modulating an N-bit input digital signal, where N is an integer of 2 or more, into a pulse signal having a pulse width corresponding to a value of the digital signal. The modulator includes a noise shaping filter configured to perform noise shaping of the input digital signal; a quantizer configured to convert an output of the noise shaping filter to an M-bit digital signal, where M is an integer smaller than N; a pulse width modulator configured to convert the output of the quantizer to the pulse signal; and a compensation circuit configured to receive the output of the quantizer and to output a compensation signal for compensating non-linear distortion of the pulse signal. The noise shaping filter receives both of the output of the quantizer and an output of the compensation circuit, and executes noise shaping.

According to this aspect, the compensation circuit is provided, which receives the output of the quantizer, and outputs the compensation signal for compensating non-linear distortion of the pulse signal. The noise shaping filter, which performs noise shaping of the input digital signal, receives both of the output of the quantizer and the output of the compensation circuit, and executes noise shaping. Thus, in order to perform feedback through the non-linear element for distortion compensation, the non-linear element can be divided into a linear portion, in which the output of the quantizer is used without change, and a non-linear portion for compensation. This increases flexibility of the processing, facilitates a change in the characteristics of the non-linear element, and increases the operational stability.

In the pulse width modulator according to the present disclosure, the non-linear element can be divided into the linear portion, in which the output of the quantizer is used without change, and the non-linear portion for compensation. This facilitates a change in the characteristics of the non-linear element, and increases the operational stability.

### BRIEF DESCRIPTION OF THE DRAWINGS

FIG. 1 is a block diagram of a pulse width modulation device according to a first embodiment.

FIG. 2 illustrates a configuration example of a noise shaping filter of FIG. 1.

FIG. 3 is a block diagram of a pulse width modulation device according to a second embodiment.

FIG. 4 is a block diagram of a pulse width modulation device according to a third embodiment.

FIG. 5 is a block diagram of a conventional pulse width modulation device.

FIG. 6 illustrates a basic noise shaping circuit.

### DETAILED DESCRIPTION

Embodiments are described in detail below with reference to the attached drawings. However, unnecessarily detailed description may be omitted. For example, detailed description of well-known techniques or description of the substantially same elements may be omitted. Such omission is intended to prevent the following description from being unnecessarily redundant and to help those skilled in the art easily understand it.

Inventor provides the following description and the attached drawings to enable those skilled in the art to fully understand the present disclosure. Thus, the description and the drawings are not intended to limit the scope of the subject matter defined in the claims.

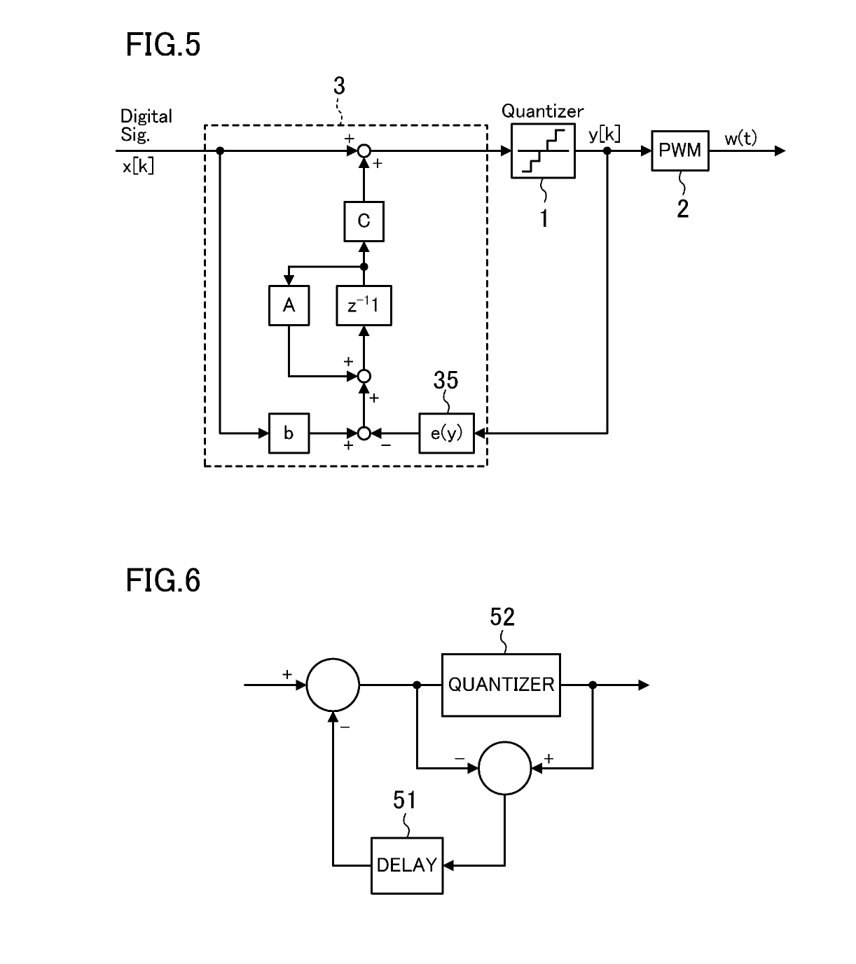

First, operation of a basic noise shaping circuit will be briefly described. FIG. 6 is a block diagram of a most simple first-order noise shaping circuit. A quantizer 52 rounds, for example, a 24-bit signal down to 6 bits to reduce the bit number of output data. Also, the input of the quantizer 52 is subtracted from the output of the quantizer 52, thereby calculating an error caused by quantization, i.e., a quantization noise.

Where the quantization noise is Vq and delay processing is Z, it is found that the following equation can be obtained from FIG. 6.

Output=Input+(1−Z)Vq

In the equation, (1−Z) means obtaining the difference between present time data and time data immediately before the present. This is the same as the definition of differentiation. Thus, the output of the circuit of FIG. 6 is the sum of the input signal and a signal obtained by differentiating the quantization noise. Considering from the side of the quantization noise, the quantization noise does not simply occur, but the differentiated noise occurs. Therefore, the circuit of FIG. 6 is called a circuit changing the shape of noise, i.e., a noise shaping circuit.

Due to the noise shaping by differentiation, the feature of the circuit of FIG. 6 is that the low frequency component of noise decreases and instead, the high frequency component increases. The smaller the amount of the change between the present data value and the data value immediately before the present is, the smaller the quantization noise added to the output is. As a result, an advantage similar to an increase in the accuracy of output data can be obtained.

The processing is used in a plurality of samples, thereby providing a higher-order noise shaping filter. The filtering can be expressed by an ABCD matrix which is generally used in the digital control theory. Japanese Patent Publication No. 2005-236928 teaches using this filtering, and compensating a distortion component occurring in a series of the filtering using non-linear processing.

### First Embodiment

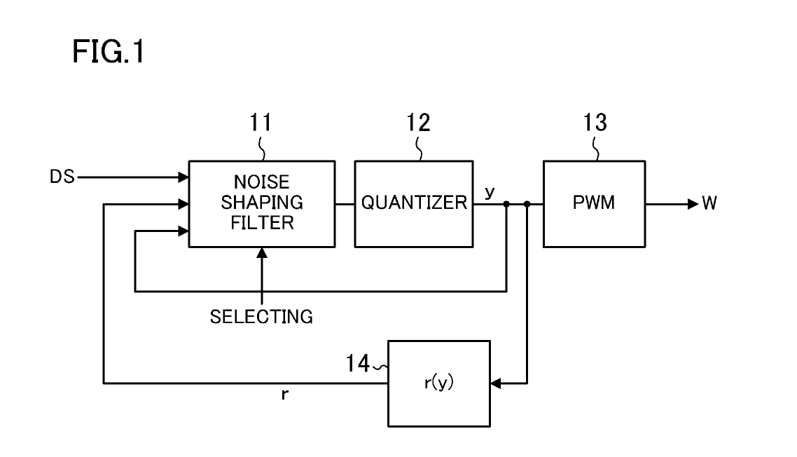

FIG. 1 is a block diagram of a pulse width modulation device according to a first embodiment. The pulse width modulation device of FIG. 1 modulates an N-bit input digital signal DS, where N is an integer of 2 or more, into a pulse signal w having a pulse width corresponding to the signal value. The pulse width modulation device is used, for example, in a full digital amplifier.

In FIG. 1, reference numeral 11 denotes a noise shaping filter performing noise shaping of the input digital signal DS. Reference numeral 12 denotes a quantizer converting an output of the noise shaping filter 11 to an M-bit digital signal y, where M is an integer smaller than N. Reference numeral 13 denotes a pulse width modulator (PWM) converting an output y of the quantizer 12 to the pulse signal w. Reference numeral 14 denotes a compensation circuit receiving the output y of the quantizer 12, and outputting a compensation signal r for compensating non-linear distortion of the output w of the pulse width modulator 13.

In this embodiment, N is 24, and M is 6. That is, the quantizer 12 converts a 24-bit digital signal, which is an output of the noise shaping filter 11 to 6 bits, i.e., 64 steps, and outputs the converted signal as a digital signal y. The pulse width modulator 13 converts the input signal y of 64 steps to the pulse signal w having 64 types of pulse widths corresponding to the steps, and outputs the converted signal. The compensation circuit 14 includes a compensation table r(y) for compensating the non-linear distortion. The compensation table r(y) defines the correspondence relationship between the 6-bit output y of the quantizer 12 and the 24-bit compensation signal r. The compensation table r(y) is prepared by subtracting the linear portion corresponding to the output y of the quantizer 12 from a conventional non-linear element table e(y).

The noise shaping filter 11 performs filter calculation based on the quantization noise, which is the difference between the 24-bit input digital signal DS and the 6-bit output signal y of the quantizer 12. The noise shaping filter 11 also performs calculation using the 24-bit compensation signal r output from the compensation circuit 14, thereby compensating the distortion.

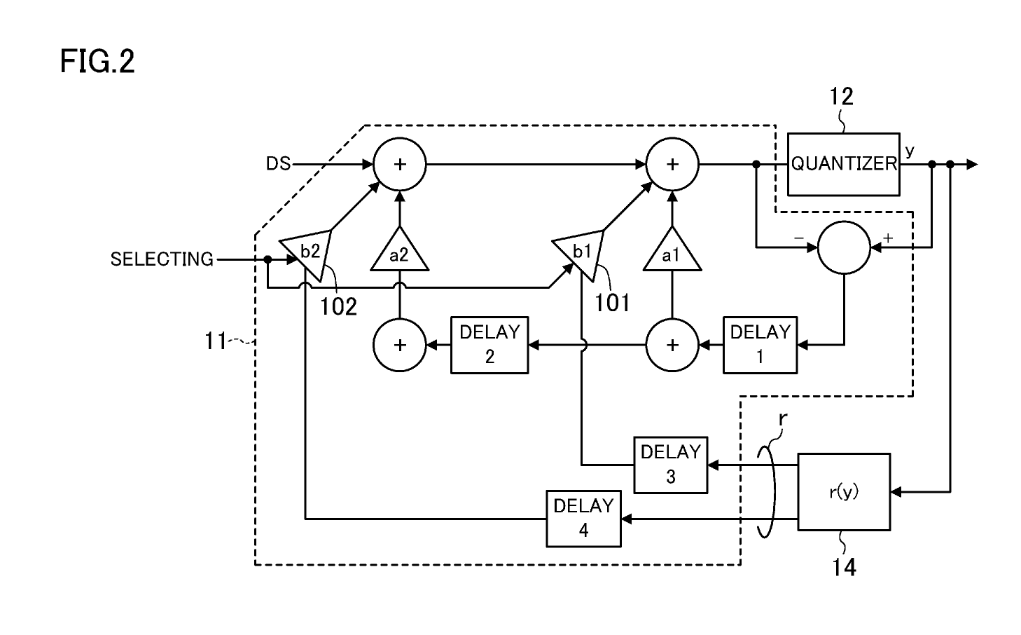

The noise shaping filter 11 is capable of controlling the compensation characteristics based on an output r of the compensation circuit 14. FIG. 2 illustrates an example configuration of the noise shaping filter 11. In FIG. 2, second-order noise shaping and addition of the compensation signal r for the distortion compensation are combined.

The characteristics of the noise shaping filter 11 are changed, for example, as follows. Where distortion compensation is to be enhanced, gains b1 and b2 of the amplifiers 101 and 102 are increased in the addition of the compensation signal r. As a result, the more effectively compensated pulse signal w can be obtained. Where distortion compensation is not to be performed, the gains b1 and b2 of the amplifiers 101 and 102 are set to zero. As such, the compensation characteristics of the noise shaping filter 11 can be easily switched.

As described above, according to this embodiment, in order to compensate non-linear distortion of the output pulse signal w, the non-linear element for compensation is divided into a linear portion, in which the output of the quantizer is used without change, and a non-linear portion for compensation. This increases flexibility of the processing, thereby facilitating switch of the characteristics.

### Second Embodiment

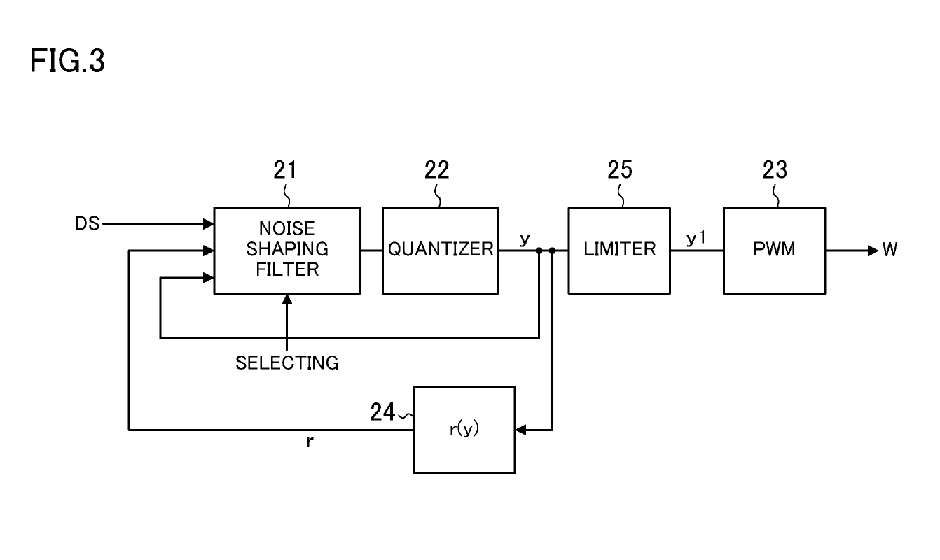

FIG. 3 is a block diagram of a pulse width modulation device according to a second embodiment. In FIG. 3, the configurations and operation of a noise shaping filter 21, a quantizer 22, a pulse width modulator 23, and a compensation circuit 24 are almost the same as the noise shaping filter 11, the quantizer 12, the pulse width modulator 13, and the compensation circuit 14 of FIG. 1. However, the number of bits and the number of steps of the signal to be processed are slightly different. In addition, a limiter 25, which limits the number of steps of the output y of the quantizer 22, is provided between the quantizer 22 and the pulse width modulator 23. The pulse width modulator 23 receives not the output y of the quantizer 22 but an output y1 of the limiter 25.

In FIG. 3, the quantizer 22 has a different number of steps from the quantizer 12 of FIG. 1. For example, the quantizer 22 outputs a 7-bit digital signal y of 74 steps, which are 10 steps more than that of the quantizer 12. The limiter 25 limits the number of steps of the digital signal y to, for example, 60 steps, and outputs the signal to the pulse width modulator 23. The pulse width modulator 23 converts the input signal y1 of 60 steps to the pulse signal w having 60 types of pulse widths corresponding to the steps. The compensation circuit 24 refers to the compensation table r(y) related to the signal y of 74 steps, which has a larger number of steps than that of the first embodiment, and outputs the compensation signal r to the noise shaping filter 21.

The noise shaping filter 21 performs filter calculation based on the quantization noise, which is the difference between the 24-bit input digital signal DS and the 7-bit output signal y of the quantizer 22. The noise shaping filter 21 also performs calculation using the 24-bit compensation signal r output from the compensation circuit 24, thereby compensating distortion. The noise shaping filter 21 has a configuration shown in, for example, FIG. 2.

As such, since the number of steps of the quantizer 22 is set large, the output y of the quantizer 22 has margin and is not saturated even if the input digital signal DS has the maximum amplitude. This stably operates the linear feedback portion. In addition, since non-linear compensation of the compensation circuit 24 can be added, the compensation can be performed without losing the stability.

Generally, a digital power amplifier has the limitation of the smallest pulse width of a PWM signal. Thus, in using the pulse width modulation device of the present disclosure in a digital power amplifier, the number of steps is limited in the limiter 25 to satisfy the limitation of the pulse width, thereby improving use efficiency of the power source.

### Third Embodiment

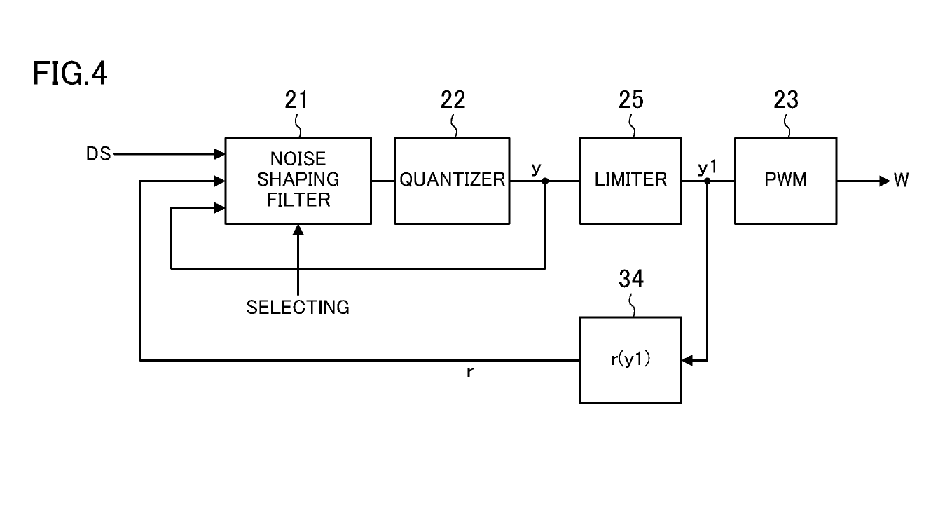

FIG. 4 is a block diagram of a pulse width modulation device according to a third embodiment. The configuration of FIG. 4 is almost the same as the configuration of FIG. 3. The configurations and operation of the noise shaping filter 21, the quantizer 22, the pulse width modulator 23, and the limiter 25 are similar to those in the second embodiment.

However, a compensation circuit 34 receives not the output y of the quantizer 22, but the output y1 of the limiter 25. Specifically, the compensation circuit 34 refers to a compensation table r(y1) related to the output y1 of the limiter 25, which has a smaller number of steps than the output y of the quantizer 22, and outputs the compensation signal r to the noise shaping filter 21. The signal y1 with the small number of steps is used as an input, thereby reducing the size of the compensation table r(y1). This reduces the circuit scale.

As compared to the second embodiment, the compensation signal r, which is not necessarily suitable for the part of steps limited by the limiter 25, is fed back to the noise shaping filter 21. However, the part of steps is limited by the limiter 25 and is originally irregular. Even if a little different PWM signal is output, the sound quality is not particularly influenced.

The pulse width modulation device according to the present disclosure is used, for example, in a digital audio power amplifier, thereby providing audio reproduction with high sound quality and high efficiency.

As described above, the first to third embodiments have been described as example techniques disclosed in the present application. However, the techniques according to the present disclosure are not limited to these embodiments, but are also applicable to those where modifications, substitutions, additions, and omissions are made. In addition, elements described in the first to third embodiments may be combined to provide a different embodiment.

Various embodiments have been described above as example techniques of the present disclosure, in which the attached drawings and the detailed description are provided.

As such, elements illustrated in the attached drawings or the detailed description may include not only essential elements for solving the problem, but also non-essential elements for solving the problem in order to illustrate such techniques. Thus, the mere fact that those non-essential elements are shown in the attached drawings or the detailed description should not be interpreted as requiring that such elements be essential.

Since the embodiments described above are intended to illustrate the techniques in the present disclosure, it is intended by the following claims to claim any and all modifications, substitutions, additions, and omissions that fall within the proper scope of the claims appropriately interpreted in accordance with the doctrine of equivalents and other applicable judicial doctrines.

What is claimed is:

1. A pulse width modulation device modulating an N-bit input digital signal, where N is an integer of 2 or more, into a pulse signal having a pulse width corresponding to a value of the input digital signal, the modulator comprising:
a noise shaping filter configured to perform noise shaping of the input digital signal;
a quantizer configured to convert an output of the noise shaping filter to an M-bit digital signal, where M is an integer smaller than N;
a pulse width modulator configured to convert an output of the quantizer to the pulse signal; and
a compensation circuit configured to receive the output of the quantizer and to output a compensation signal for compensating non-linear distortion of the pulse signal, wherein
the noise shaping filter executes noise shaping upon receipt of both of the output of the quantizer, and an output of the compensation circuit.

2. The pulse width modulation device of claim 1, further comprising:
a limiter provided between the quantizer and the pulse width modulator, and configured to limit a number of steps of the output of the quantizer, wherein
the pulse width modulator receives an output of the limiter instead of the output of the quantizer.

3. The pulse width modulation device of claim 2, wherein
the compensation circuit receives the output of the limiter instead of the output of the quantizer.

4. The pulse width modulation device of claim 1, wherein
the noise shaping filter is capable of controlling compensation characteristics based on the output of the compensation circuit.
